(19) United States
(12) Patent Application Publication
(10) Pub. No.: US 2015/0079283 A1
(43) Pub. Date: Mar. 19, 2015

(54) APPARATUS AND METHOD TO DEPOSIT DOPED FILMS

(71) Applicant: LGS Innovations LLC, Herndon, VA (US)

(72) Inventors: Brijesh Vyas, Herndon, VA (US); Mike Santo, Herndon, VA (US); Hugo Safar, Herndon, VA (US)

(73) Assignee: LGS Innovations LLC, Herndon, VA (US)

(21) Appl. No.: 14/026,953

(22) Filed: Sep. 13, 2013

(51) Int. Cl. C23C 16/448

(52) U.S. Cl. CPC C23C 16/4481
USPC 427/255.28; 118/715; 118/719; 427/255.23

(57) ABSTRACT

A deposition apparatus comprising a vaporizer chamber configured to hold a solid precursor of a dopant element therein. Gas input and output lines are connected to the vaporizer chamber and flow rate controllers are coupled to each of the gas input and output lines. The flow rate controllers are configured to adjust a rate of carrier gas flow into and out of the vaporizer chamber through the gas input and output lines. The vaporizer chamber has a temperature controller and pressure controller to produce vapors of the solid precursor in the vaporizer chamber that can be carried with the carrier gas flow through the output line.

### ACKNOWLEDGEMENT OF GOVERNMENT SUPPORT

This disclosure was made with government support under Government Contract No. FA9451-10-C-0273

### TECHNICAL FIELD

The invention relates to in general, a deposition apparatus and process.

### BACKGROUND

This section introduces aspects that may help facilitate a better understanding of the inventions. Accordingly, the statements of this section are to be read in this light and are not to be understood as admissions about what is prior art or what is not prior art.

Deposition processes to form doped films can include sputtering, pulsed laser ablation, sol-gel deposition, ion exchange or ion implantation. Often, however, these processes are cumbersome and the rate of deposition is very slow, e.g., hours to deposit a film of a few microns in thickness, and therefore these processes are not suitable for industrial production.

### SUMMARY

One embodiment is a deposition apparatus comprising a vaporizer chamber configured to hold a solid precursor of a dopant element therein. Gas input and output lines are connected to the vaporizer chamber and flow rate controllers are coupled to each of the gas input and output lines. The flow rate controllers are configured to adjust a rate of carrier gas flow into and out of the vaporizer chamber through the gas input and output lines. The vaporizer chamber has a temperature controller and pressure controller to produce vapors of the solid precursor in the vaporizer chamber that can be carried with the carrier gas flow through the output line.

In some such embodiments, the dopant element of the solid precursor in the vaporizer chamber is a single element type. In any such embodiments, the apparatus can be further configured to allow a passage of the carrier gas flow through a porous frit connected to the end of the gas input line in the vapor chamber. In any such embodiments, the flow rate controllers can be configured to adjust the flow rate of the carrier gas flow into and out of the vaporizer chamber to substantially match a vapor forming rate of the solid precursor of the dopant element in the vapor chamber.

Any such embodiments can further include a vaporizer module having a plurality of the vaporizer chambers each configured to hold a different solid precursor of a different dopant element therein. There can be separate pairs of the gas input and output lines connected to each of the vaporizer chambers, and separate pairs of the flow rate controllers coupled to each of the gas input and output lines, wherein the flow rate controllers separately adjust a rate of the carrier gas flow into and out of the each of the vaporizer chambers. Each of the vaporizer chambers can have separately controllable temperature controllers and pressure controllers to produce vapors of each of the different solid precursors in each of the vaporizer chambers to thereby produce different vapors of the precursors of the dopant elements that can be carried with the carrier gas through the output lines. In some such embodiments, one of the vapor chambers can hold the solid precursor of the dopant element of aluminum and another one of the vapor chambers holds the solid precursor of the dopant element of a rare earth element. In some such embodiments, one of the vapor chambers can hold the solid precursor of the dopant element of ytterbium and another one of the vapor chambers holds the solid precursor of the dopant element of a rare earth element other than ytterbium.

Any such embodiment can further including a reactor assembly located inside of a deposition chamber of the apparatus, the reactor assembly receiving as a first input the vapor forms of the precursors of the dopant elements transported from the output line. In some such embodiments, the reactor assembly can be further configured to receives as a second input having vapor forms of precursor gases for a doped film to be formed in the deposition chamber. In some such embodiments, the reactor assembly can be configured to receive different vapor precursors of different types of the dopant elements separately formed in different ones of the vaporizer chambers. In some such embodiments, the reactor assembly can be configured to receives as the first input, the vapor forms of the precursors of the dopant elements of a rare earth element and one of aluminum and ytterbium, and as the second input, a gas precursor for the doped film.

Another embodiment is a method comprising generating a vapor form of a solid precursor of a dopant element. The solid precursor of the dopant element is placed into a vaporizer chamber. Gas input and output lines are connected to the vaporizer chamber and flow rate controllers are coupled to each of the gas input and output lines. A temperature and pressure inside of the vaporizer chamber is controlled to produce the vapor form of the solid precursor of the dopant element. A flow rate of carrier gas into and out of the vaporizer chamber is adjusted through the gas input and output lines to carry the vapor form of the solid precursor of the dopant element through of the output line.

In some such embodiments, adjusting the flow rate of the carrier gas flow into and out of the vaporizer chamber substantially matches a forming rate of the vapors of the solid precursor of the dopant element in the vaporizer chamber.

Any such embodiments can further include generating a vapor form of a second solid precursor of a second dopant element including. Generating the vapor form can include placing the second solid precursor of the second dopant element into a second vaporizer chamber, wherein second gas input and output lines are connected to the second vaporizer chamber and second flow rate controllers are coupled to each of the second gas input and output lines. Generating the vapor form can include controlling a temperature and pressure inside of the second vaporizer chamber to produce a vapor of the second vapor form of the solid precursor of the second dopant element. Generating the vapor form can include adjusting a flow rate of the carrier gas into and out of the second vaporizer chamber through the second gas input and output lines to carry the vapor form of the second solid precursor of the second dopant element through of the second output line.

In some such embodiments, adjusting the flow rate of the carrier gas flow into and out of the second vaporizer chamber substantially matches a forming rate of the vapors of the second solid precursor of the second dopant element in the second vaporizer chamber. In some such embodiments, the vapor form of the solid precursor, and the vapor form of the second solid precursor, can be simultaneously delivered through the first and second outline lines, respectively, to a common line connected to a deposition chamber. In some such embodiments, the vapor form of the solid precursor, and the vapor form of the second solid precursor, can be alternately delivered through the first and second outline lines, respectively, to a common input line connected to a deposition chamber of the apparatus.

Any such embodiments, can further include forming a doped film on a substrate, including delivering the vapor form of the solid precursor of the dopant element to a reactor assembly located inside of a deposition chamber. In some such embodiments, forming the doped film further can include delivering a film deposition gases of the doped film to the reactor assembly concurrently with the delivery of the vapor form of the solid precursor of the dopant element. In some such embodiments, forming the doped film further includes simultaneously delivering vapor forms of the solid precursors of different types of the dopant elements, which are separately formed in different vaporizer chambers, to the reactor assembly.

### BRIEF DESCRIPTION OF THE DRAWINGS

The embodiments of the disclosure are best understood from the following detailed description, when read with the accompanying figures. Some features in the figures may be described as, for example, “top,” “bottom,” “vertical” or “lateral” for convenience in referring to those features. Such descriptions do not limit the orientation of such features with respect to the natural horizon or gravity. Various features may not be drawn to scale and may be arbitrarily increased or reduced in size for clarity of discussion. Reference is now made to the following descriptions taken in conjunction with the accompanying drawings, in which:

FIG. 1 presents a block diagram of an apparatus; and

FIG. 2 presents a flow diagram of a method of use such as a method of using any of the apparatuses described in the context of FIG. 1.

In the Figures and text, similar or like reference symbols indicate elements with similar or the same functions and/or structures.

In the Figures, the relative dimensions of some features may be exaggerated to more clearly illustrate one or more of the structures or features therein.

Herein, various embodiments are described more fully by the Figures and the Detailed Description. Nevertheless, the inventions may be embodied in various forms and are not limited to the embodiments described in the Figures and Detailed Description of Illustrative Embodiments.

### DETAILED DESCRIPTION OF ILLUSTRATIVE EMBODIMENTS

The description and drawings merely illustrate the principles of the inventions. It will thus be appreciated that a person of ordinary skill in the relevant arts will be able to devise various arrangements that, although not explicitly described or shown herein, embody the principles of the inventions and are included within its scope. Furthermore, all examples recited herein are principally intended expressly to be for pedagogical purposes to aid the reader in understanding the principles of the inventions and concepts contributed by the inventor(s) to furthering the art, and are to be construed as being without limitation to such specifically recited examples and conditions. Moreover, all statements herein reciting principles, aspects, and embodiments of the inventions, as well as specific examples thereof, are intended to encompass equivalents thereof. Additionally, the term, “or,” as used herein, refers to a non-exclusive or, unless otherwise indicated. Also, the various embodiments described herein are not necessarily mutually exclusive, as some embodiments can be combined with one or more other embodiments to form new embodiments.

Described herein is an apparatus and process to facilitate deposition processes to form doped films. In some cases the film can be an optical quality film used as a component part of planar lightwave circuits (PLCs). In some embodiments, the apparatus and processes described herein can facilitate the formation of aluminum doped films, rare earth element doped films, or combinations of aluminum and rare earth element doped films. The use of aluminum as a co-deposited modifier for the rare earth element doped films can advantageous allow for higher concentrations of active rare earth element doping in the film and facilitate producing a broad emission spectrum from the doped film.

The deposition process and apparatus further described below can facilitate the formation of uniform and constant concentration of the rare earth element and/or aluminum across the thickness of the doped film having a thickness of several microns in shorter periods (e.g., minutes) than certain other types of deposition processes.

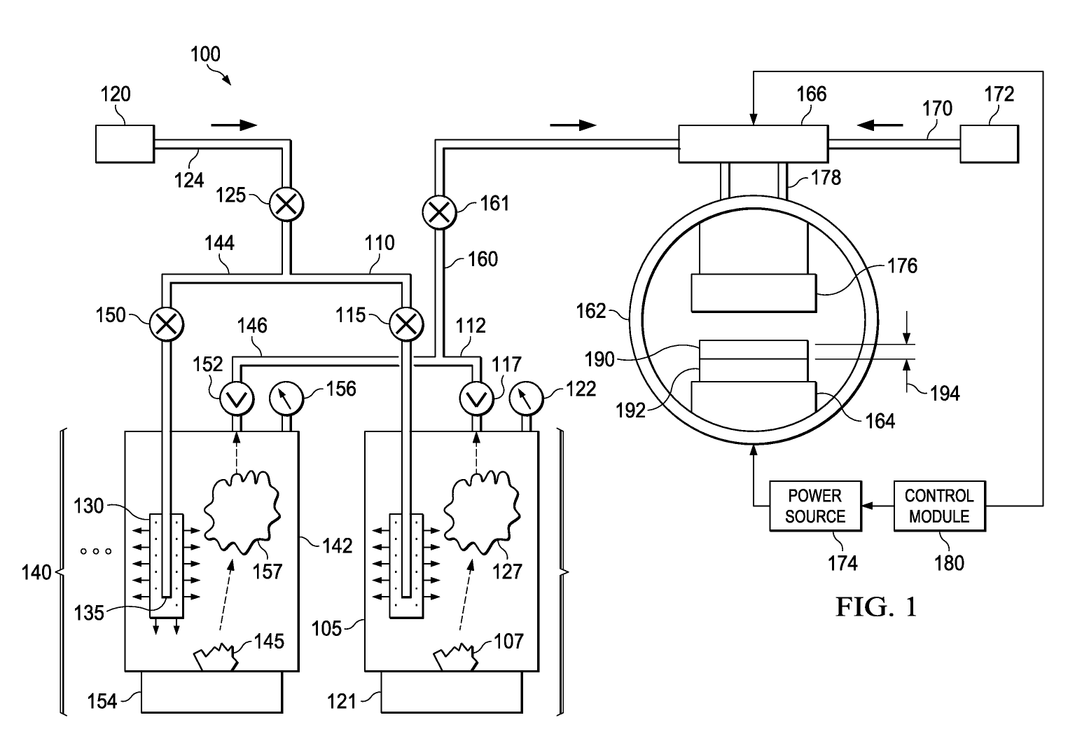

One embodiment is a deposition apparatus. FIG. 1 presents a block diagram of an apparatus 100.

In some embodiments, the deposition apparatus 100 can be or include chemical vapor deposition (CVD apparatus, such as a plasma enhanced chemical vapor deposition (PECVD) apparatus, or a metal organic chemical vapor deposition (MOCVD) apparatus. One of ordinary skill in the pertinent arts would understand from this disclosure how to make and use other embodiments of the deposition apparatus.

As illustrated for the embodiment shown in FIG. 1, the apparatus 100 comprises a vaporizer chamber 105 configured to hold a solid precursor 107 of a dopant element therein. The apparatus 100 also comprises gas input and output lines 110, 112 connected to the vaporizer chamber 105. The apparatus 100 also comprises flow rate controllers 115, 117, e.g., on/off valve and needle valves, respectively, in some embodiments. The flow rate controllers, configured as input and output flow rate controllers 115, 117, respectively, can be coupled to each of the gas input and output lines 110, 112. The flow rate controllers 115, 117 are configured to adjust a rate of carrier gas flow 120 into and out of the vaporizer chamber through the gas input and output lines 110, 112. The vaporizer chamber 105 has a temperature controller 121 and pressure controller 122 to produce vapors of the solid precursor 127 in the vaporizer chamber 105 that can be carried with the carrier gas flow 120 (e.g., helium or other inert gases) through the output line 112. As illustrated, in some embodiments the carrier gas 120 is transferred to the input line 110 via a common input line 124 having its own flow controller 125.

The temperature controller 121 can include a temperature monitor and heater and the pressure controller 122, can include a pressure monitor, to facilitate producing a combination of increased temperature and pressure inside of the vaporizer chamber 105. In some embodiments, depending on the type of solid precursor 107 used, the production of the vapors 127 of the solid precursor 107 can be formed via direct sublimation of the solid precursor 107, while in other embodiments, vapors 127 of the solid precursor 107 can be formed via vaporization of a liquid state of the solid precursor 107. Advantages of using a solid precursor of aluminum, or of rare earth elements, include avoiding the need to handle toxic and/or explosive liquid forms of precursors of such elements. In some embodiments the vapors 127 of the solid precursor 107, including aluminum solid precursors can be formed at relatively low temperatures (e.g., about 700° C. or less) compared to certain other deposition processes.

Examples ligand of the solid precursor 107 include metal beta-diketonate ligand complexes such as tris(2,2,6,6-tetramethyl-3,5-heptanedionato) (TMHD) rare earth element ion (III) or aluminum ion (III) complexes. Non-limiting examples include Yb(TMHD)₃, Er(TMHD)₃, Ho(TMHD)₃, Tm(TMHD)₃, or Al(TMHD)₃. Other examples of the solid precursor include metal fluorobeta-diketonate ligand complexes such as Tris(6,6,7,7,8,8,8-heptafluoro-2,2-dimethyl-3,5-octanedionate) (FOD) rare earth element ion (III) or aluminum ion (III) complexes. Non-limiting examples include Yb(FOD)₃, Er(FOD)₃, or Al(FOD)₃. Other examples of the solid precursor include metal metallocene ligand complexes such rare earth element ion (III) or aluminum ion (III) metallocene complexes. Non-limiting examples include Tris(i-propylcyclopentadienyl) Er. Other examples of the solid precursor include the aluminum(III) acetylacetonate ligand complex (Al(acac)₃). One skilled in the pertinent arts would understand that other types of ligands could be used to form the solid precursor.

In some embodiments, the dopant element of the solid precursor 107 placed in the vaporizer chamber 105 is a single metal element type, for example aluminum only, or, a single rare earth element type only. Using a single metal element type in the chamber 105, or a different metal element type in each of multiple different chambers, provides the advantage of allowing precise control of the conditions to form uniform amounts of the vapors of the solid precursor 127. This can be advantageous when the solid precursors of different elements have widely different melting points and sublimation pressures or vaporization pressures. In some embodiments, however, there can be multiple different solid precursors 107 of different dopant elements in a single chamber 105.

Similarly, in some embodiments, the dopant element of the solid precursor 107 placed in the vaporizer chamber 105 is a single ligand type, for example only TMHD, only FOD, only metallocene or only acac. Using a single ligand type in the chamber 105, provides the advantage of allowing precise control of the conditions to form uniform amounts of the vapors of the solid precursor 127. In some embodiments, however, there can be multiple different solid precursors 107 of different ligand types in a single chamber 105.

In some embodiments, the solid precursor 107 placed in the vaporizer chamber 105 has a single ligand type and a single dopant element type. For instance, in some embodiments the single solid precursor 107 type can be Al(acac)₃. Aluminum doped semiconductors can increase the electrical conductivity of certain doped films, such as aluminum doped GaN- or GsAs-films used in electrical semiconductor transistors. For instance, in some embodiments, the single solid precursor 107 type can be one of Er(TMHD)₃, Ho(TMHD)₃, or Tm(TMHD)₃. Such rare earth element doped films can improve light emission from active optical device components in photonic integrated circuit such as diodes, lasers or light amplifiers or other active device components familiar to those skilled in the pertinent art.

As further illustrated in FIG. 1, in some embodiments, the carrier gas flow 120 passes through a porous frit 130 (e.g., a porous metal, glass or ceramic frit) connected to an end 135 of the gas input line 110 in the vapor chamber 105. Passing the carrier gas through the porous frit 130 can facilitate uniform mixing of the vapors of the solid precursor 127 into the carrier gas stream exiting the chamber 105 through the output line 112.

In some embodiments, it is desirable to provide a uniform concentration of the vapor form 127 of the solid precursor 107 in the outlet line 112. Having a uniform concentration of the vapor form 127 in the outlet line 112, in turn, can facilitate forming a doped film with a uniform concentration of the dopant element throughout the entire thickness of the film. To provide the uniform concentration of the vapor form 127 in the outlet line 112 the flow rate controllers 115, 117 (e.g., via precision valves) can adjust the flow rate of the carrier gas flow into and out of the vaporizer chamber 105 to substantially match a vapor 127 forming rate of the solid precursor 107 of the dopant element in the vaporizer chamber 105. That is, for a given temperature and pressure in the chamber 105 that produces vapors of the solid the precursor 127, the flow rate of the carrier gas flow 120 into and out of the vaporizer chamber 105 is adjusted to value that removes the vapor 127 from the chamber at a same rate, e.g., within about 10 percent and in some embodiments within about 1 percent, that the vapor form 127 of the solid precursor 107 is being produced at. One skilled in the pertinent art would understand how in a calibration process, a doped film could be analyzed to measure the distribution of dopant concentrations therein, and then adjust the flow rate controllers 115, 117 accordingly to provide the desired uniformity of dopant in the film.

As also illustrated in FIG. 1, some embodiments the apparatus 100 further include a vaporizer module 140 having a plurality of the vaporizer chambers (e.g., chambers 105, 142) each chamber configured to hold a different solid precursor of a different dopant elements 107, 145 therein. For example, Er(TMHD)₃ can be the solid precursor 107 in one chamber 105 and Al(acac)₃ can be the solid precursor 145 in another chamber 142).

For some such embodiments, separate pairs of the gas input and output lines are connected to each of the vaporizer chambers 105, 142 (e.g., first input and output lines 110, 112 and second input and output lines 144, 146, respectively).

For some such embodiments, separate pairs of the flow rate controllers (e.g., first controllers 115, 117 and second controllers 150, 152) are coupled to each of the gas input and output lines (e.g., lines 110, 112 and 144, 146, respectively). The flow rate controllers 115, 117, 150, 152 can be configured to separately adjust a rate of the carrier gas flow 120 into and out of the each of the vaporizer chambers 105, 142, e.g., to match distinct vapor forming rates from different solid precursors 107, 145 in each chamber 105, 142.

For some such embodiments, each of the vaporizer chambers 105, 142 have separately controllable temperature controllers and pressure controllers (e.g., temperature and pressure controllers 121, 122 and 154, 156, respectively) to produce vapors 127, 157 of each of the different solid precursors 107, 145 in each of the vaporizer chambers 107, 142. The separately produced vapors 127, 157 can be carried with the carrier gas 120 through the output lines 112, 146 of the chambers 105, 142.

Because each vaporizer chamber 105, 142 can have its own temperature, pressure and flow controllers, the individual amount and the ratios of the various elements deposited in the doped film can be precisely controlled.

In some embodiments, two or more vaporizer chambers 105, 142 of the module 140 are used concurrently to simultaneously deposit different dopant elements present in each of chambers.

For instance, in some embodiments, one of the vapor chambers (e.g., chamber 105) can hold the solid precursor 107 of the dopant element of aluminum (e.g., Al(acac)₃), and, another one of the vapor chambers (e.g., chamber 142) can hold the solid precursor 145 of the dopant element of a rare earth element (e.g., a rare element complex with one of (TMHD)₃, FOD, or metallocene) ligands. Vapors of solid precursor of these dopant elements 127, 157 can be simultaneously carried with the carrier gas flow 120 through the output lines 112, 146, respectively. The inclusion of aluminum can facilitate having a higher concentration of active rare earth dopant in doped films, and, facilitate a broad emission spectrum generated in the doped film.

A simultaneous deposition of vapors of both aluminum and rare element dopants (e.g., vapors 127, 157) promotes having uniform and constant concentrations of the dopants through the entire thickness of the film. In some embodiments, a combined flow of the vapors 127, 157 of solid precursors of these dopant elements has an atomic ratio of aluminum to the individual different types of rare earth elements of at least about 3:1, and in some embodiments, an atomic ratio of aluminum to rare earth elements in a range of about 5:1 to 20:1. For instance, such atomic ratios of aluminum to rare earth elements can be present in a combined output line 160 that combines the output lines (e.g., lines 112, 146) from all of the chambers 105, 142 of the apparatus 100. Such atomic ratios of aluminum to rare earth elements can be delivered to the doped film to be formed. As illustrated the combined line 160 can have its own separate flow rate controller 161.

For instance, in some embodiments, one vaporizer chamber 105 can hold the solid precursor 107 of the dopant element of ytterbium (e.g., Yb(TMHD)₃), and, another one of the vaporizer chambers 142 can hold the solid precursor 145 of the dopant element of a rare earth element other than ytterbium (e.g., Er(TMHD)₃). The inclusion of ytterbium can facilitate enhanced light emission rare earth dopants in doped film, such as light emission from erbium doped films in the 1.5 micron wavelength range. For instance, in some embodiments, one chamber 107 can hold the solid precursor 107 of the dopant element of holmium (e.g., Ho(TMHD)₃), and, another one of the chambers 142 can hold the solid precursor 145 of the dopant element of a rare earth element of thulium (e.g., Tm(TMHD)₃). The combination of holmium and thulium in the doped film can facilitate the formation of a light emission band in the 2 micron wavelength range.

One skilled in the pertinent arts would appreciate how similar processes can be used to simultaneously deposit multiple different dopant elements in the doped film.

In some embodiments, however, only one vaporizer chamber (e.g., one of chambers 107 or 142) is operated at a time to sequentially deposit different dopants from each of the chambers. For instance, a doped film can be formed using the apparatus 100 such that different type of rare element elements or other dopants are present at different regions through the thickness of the film.

As further illustrated in FIG. 1, in some embodiments, the apparatus 100 can further include other components, e.g., components of a CVD apparatus. Such components can include a deposition chamber 162, heating module 164, and gas delivery system 166 to control the inlet and outlet of deposition materials into and out of the deposition chamber 162.

In some embodiments, a combined output line 160, that combines the output lines 112, 146, from all of the vaporizer chambers 105, 142 can be an input line connected to the gas delivery system 166, or in other cases directly connected to the deposition chamber 162. As illustrated, a separate delivery line 170 can be configured to deliver film deposition gases 172 to the gas delivery system 166 or in other cases directly connected to the deposition chamber 162. Non-limiting examples of the film deposition gases 172 include tetraethoxysilane (TEOS), silane (SiH₄), germane (GeH₄) and phosphine (PH₃).

Some embodiments of the apparatus 100 can further include a radio-frequency power source 174 used to generate a plasma inside of a reactor assembly 176 located inside of the deposition chamber 162. The reactor assembly 176 can be configured to receive as a first input the vapor forms of the precursors of the dopant elements (e.g., precursors vapors 127, 157) transported from the combined output line 160 (or single output line 112, in some embodiments).

The reactor assembly 176 can be further configured to receive as a second input, the film deposition gases 172 for a doped film 190 to be formed in the deposition chamber 162. In some embodiments, the film deposition gases 172 can be separately delivered to the reactor assembly 176 via separate delivery line 170. In other embodiments the film deposition gases 172 can be delivered via a gas delivery system 166 which in turn receives both of the vapor forms of the precursors of the dopant elements 127, 157, and, the film deposition gases 172 and then delivers the vapors 127, 157, and gases 172 to the reactor assembly 176 via a separate inlet line 178.

A control module 180 (e.g., a computer) of the apparatus 100 can be configured to control the flow of deposition material, and/or, the deposition chamber's pressure and temperature and/or the deposition substrate's temperature.

In some embodiments, the reactor assembly 176 can be controlled to receive, e.g., along with the film deposition gases 172, different vapor precursors of different types of the dopant elements (e.g., vapors 127, 157) separately formed in different vaporizer chambers (e.g., chambers 105, 142 of the vaporizer module 140). For instance, in some embodiments, the reactor assembly 176 receives as the first input, the vapor forms of the precursors of the dopant elements of a rare earth element and one of aluminum and ytterbium, and as the second input, a gas precursor of tetraethoxysilane (TEOS) or SiH₄, for the doped film 190.

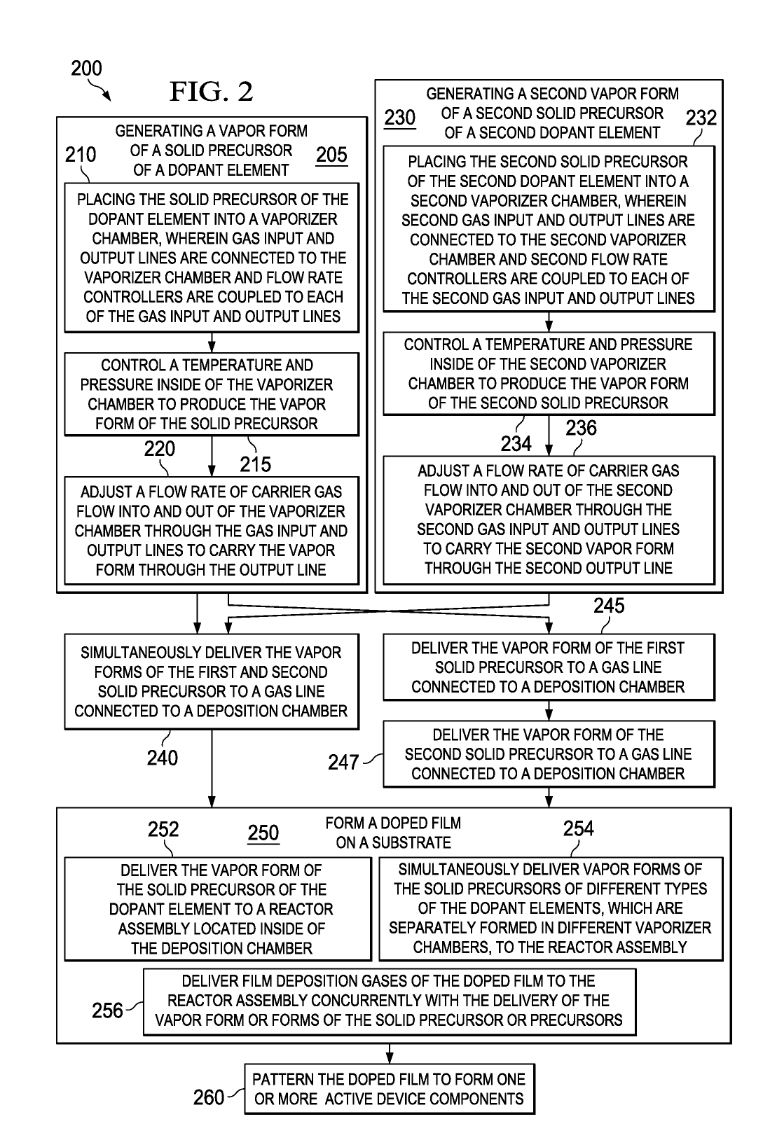

Another embodiment is a method, e.g., a method of forming a doped film. FIG. 2 presents a flow diagram of an example method 200, such as implemented by any of the apparatuses 100 described in the context of FIG. 1. With continuing reference to FIG. 1, the method comprises a step 205 of generating a vapor form 127 of a solid precursor of a dopant element 107.

Generating the vapor form 127 in step 205 includes a step 210 of placing the solid precursor 107 of the dopant element into a vaporizer chamber 105, wherein gas input and output lines 110, 112 are connected to the vaporizer chamber 105 and flow rate controllers 115, 117 are coupled to each of the gas input and output lines 110, 112.

Generating the vapor form 127 in step 205 also includes a step 215 of controlling a temperature and pressure inside of the vaporizer chamber 105 (e.g., via temperature and pressure controllers 121, 122) to produce the vapor form 127 of the solid precursor 107. Generating the vapor form 127 in step 205 further includes a step 220 of adjusting a flow rate of carrier gas 120 flow into and out of the vaporizer chamber 105 through the gas input and output lines to carry the vapor form 127 through the output line 112.

In some embodiments, as part of adjusting step 220, the carrier gas flow 120 into and out of the vaporizer chamber 105 substantially matches a vapor forming rate of the vapors of the solid precursor of the dopant element 127 in the chamber 105. For instance, if the vapor form 127 were being generated at a rate of 100 arbitrary volume units per minute, then the carrier gas flow 120 into and out of the vaporizer chamber 105 is adjusted to a flow rate of 100 volume units per minute within ±10 percent in some embodiments, within ±1 percent.

Some embodiments of the method 200 further include a step 230 of generating a vapor form 157 of a second solid precursor of a second dopant element 145. Generating the second vapor form 157 in step 230 can include a step 232 of placing the second solid precursor of the second dopant element 145 into a second vaporizer chamber 142. Second gas input and output lines 144, 146 are connected to the second vaporizer chamber 142 and second flow rate controllers are coupled to each of the second gas input and output lines 144, 146. Generating the second vapor form 157 in step 230 can also include a step 234 of controlling a temperature and pressure inside of the second vaporizer chamber 142 to produce the second vapor 157 in the second vaporizer chamber 142. Generating the second vapor form 157 in step 230 can further include a step 236 of adjusting a flow rate of the carrier gas 120 into and out of the second vaporizer chamber 142 through the second gas input and output lines 144, 146 to carry the second vapor form 157 through the second output line 146. As part of the adjusting step 236 the flow rate of the carrier gas flow 120 into and out of the second vaporizer chamber 142 substantially matches a forming rate of the vapors of the second solid precursor of the second dopant element 157 in the chamber 142.

In some embodiments of the method 200, the vapor form 127 of the solid precursor 107, and the vapor form 157 of the second solid precursor 145, are simultaneously delivered in step 240 through the first and second outline lines 112, 146, respectively, to a gas line 160 (e.g., a combined or common line 160 in some embodiments) connected to a deposition chamber 162.

In other embodiments of the method 200, the vapor form of the solid precursor 127, and the vapor form of the second solid precursor 157, are alternately delivered in step 245, 247 through the first and second outline lines 117, 146, respectively, to a line 160 connected to a deposition chamber 162.

Some embodiments of the method 200 further include a step 250 of forming a doped film 190 on a substrate 192. In some embodiment the doped film has thickness 194 in a range of 1 to 7 microns. Forming the doped film 190 in step 250 can include a step 252 of delivering the vapor form 127 of the solid precursor of the dopant element 107 to a reactor assembly 176 located inside of the deposition chamber 162.

In some embodiments, forming the doped film 190 (step 250) can include a step 254 of delivering film deposition gases 172 of the doped film 190 to the reactor assembly 176 concurrently with the delivery of the vapor form 127 (or forms 127, 157) of the solid precursor 107 (or precursors (107, 145).

In some embodiments, forming the doped film 190 (step 250) can include simultaneously delivering vapor forms 127, 157 of the solid precursors of different types of the dopant elements 107, 145, which are separately formed in different vaporizer chambers 105, 142, to the reactor assembly 176.

Some embodiments of the method 200 further include a step 260 of including patterning the doped film 190 to form one or more active device components (e.g., diodes, lasers or light amplifiers) of a planar lightwave circuit. One skilled in the pertinent arts would be familiar with lithographic and etching processes to pattern the film in accordance with step 260.

Although the present disclosure has been described in detail, a person of ordinary skill in the relevant arts should understand that they can make various changes, substitutions and alterations herein without departing from the scope of the invention.

What is claimed is:

1. A deposition apparatus, comprising:
a vaporizer chamber configured to hold a solid precursor of a dopant element therein;
gas input and output lines connected to the vaporizer chamber; and
flow rate controllers coupled to each of the gas input and output lines, wherein the flow rate controllers are configured to adjust a rate of carrier gas flow into and out of the vaporizer chamber through the gas input and output lines,
wherein the vaporizer chamber has a temperature controller and pressure controller to produce vapors of the solid precursor in the vaporizer chamber that can be carried with the carrier gas flow through the output line.

2. The apparatus of claim 1, wherein the dopant element of the solid precursor in the vaporizer chamber is a single element type.

3. The apparatus of claim 1, configured to allow a passage of the carrier gas flow through a porous frit connected to the end of the gas input line in the vapor chamber.

4. The apparatus of claim 1, wherein the flow rate controllers are configured to adjust the flow rate of the carrier gas flow into and out of the vaporizer chamber to substantially match a vapor forming rate of the solid precursor of the dopant element in the vapor chamber.

5. The apparatus of claim 1, further including a vaporizer module having a plurality of the vaporizer chambers each configured to hold a different solid precursor of a different dopant element therein, wherein:
there are separate pairs of the gas input and output lines connected to each of the vaporizer chambers,
separate pairs of the flow rate controllers coupled to each of the gas input and output lines, wherein the flow rate controllers separately adjust a rate of the carrier gas flow into and out of the each of the vaporizer chambers, and
each of the vaporizer chambers have separately controllable temperature controllers and pressure controllers to produce vapors of each of the different solid precursors in each of the vaporizer chambers to thereby produce different vapors of the precursors of the dopant elements that can be carried with the carrier gas through the output lines.

6. The apparatus of claim 5, wherein one of the vapor chambers holds the solid precursor of the dopant element of aluminum and another one of the vapor chambers holds the solid precursor of the dopant element of a rare earth element.

7. The apparatus of claim 5, wherein one of the vapor chambers holds the solid precursor of the dopant element of ytterbium and another one of the vapor chambers holds the solid precursor of the dopant element of a rare earth element other than ytterbium.

8. The apparatus of claim 1, further including a reactor assembly located inside of a deposition chamber of the apparatus, the reactor assembly receiving as a first input the vapor forms of the precursors of the dopant elements transported from the output line.

9. The apparatus of claim 8, wherein the reactor assembly is further configured to receive as a second input, vapor forms of precursor gases for a doped film to be formed in the deposition chamber.

10. The apparatus of claim 8, wherein the reactor assembly is configured to receive different vapor precursors of different types of the dopant elements separately formed in different ones of the vaporizer chambers.

11. The apparatus of claim 9, wherein the reactor assembly is configured to receive as the first input, the vapor forms of the precursors of the dopant elements of a rare earth element and one of aluminum and ytterbium, and as the second input, a gas precursor for the doped film.

12. A method, comprising:
generating a vapor form of a solid precursor of a dopant element, including:
placing the solid precursor of the dopant element into a vaporizer chamber, wherein gas input and output lines are connected to the vaporizer chamber and flow rate controllers are coupled to each of the gas input and output lines;
controlling a temperature and pressure inside of the vaporizer chamber to produce the vapor form of the solid precursor of the dopant element; and
adjusting a flow rate of carrier gas into and out of the vaporizer chamber through the gas input and output lines to carry the vapor form of the solid precursor of the dopant element through of the output line.

13. The method of claim 12, wherein adjusting the flow rate of the carrier gas flow into and out of the vaporizer chamber substantially matches a forming rate of the vapors of the solid precursor of the dopant element in the vaporizer chamber.

14. The method of claim 12, further including:
generating a vapor form of a second solid precursor of a second dopant element including:
placing the second solid precursor of the second dopant element into a second vaporizer chamber, wherein second gas input and output lines are connected to the second vaporizer chamber and second flow rate controllers are coupled to each of the second gas input and output lines;
controlling a temperature and pressure inside of the second vaporizer chamber to produce a vapor of the second vapor form of the solid precursor of the second dopant element;
adjusting a flow rate of the carrier gas into and out of the second vaporizer chamber through the second gas input and output lines to carry the vapor form of the second solid precursor of the second dopant element through of the second output line.

15. The method of claim 14, wherein adjusting the flow rate of the carrier gas flow into and out of the second vaporizer chamber substantially matches a forming rate of the vapors of the second solid precursor of the second dopant element in the second vaporizer chamber.

16. The method of claim 14, wherein the vapor form of the solid precursor, and the vapor form of the second solid precursor, are simultaneously delivered through the first and second outline lines, respectively, to a common line connected to a deposition chamber.

17. The method of claim 14, wherein the vapor form of the solid precursor, and the vapor form of the second solid precursor, are alternately delivered through the first and second outline lines, respectively, to a common input line connected to a deposition chamber of the apparatus.

18. The method of claim 12, further including:
forming a doped film on a substrate, including:
delivering the vapor form of the solid precursor of the dopant element to a reactor assembly located inside of a deposition chamber.

19. The method of claim 18, wherein forming the doped film further includes delivering a film deposition gases of the doped film to the reactor assembly concurrently with the delivery of the vapor form of the solid precursor of the dopant element.

20. The method of claim 18, wherein forming the doped film further includes simultaneously delivering vapor forms of the solid precursors of different types of the dopant elements, which are separately formed in different vaporizer chambers, to the reactor assembly.
